(19) United States
(12) Patent Application Publication
(10) Pub. No.: US 2025/0143062 A1
(43) Pub. Date: May 1, 2025

(54) LIGHT-EMITTING DEVICE, DISPLAY PANEL, DISPLAY APPARATUS AND METHOD FOR MANUFACTURING LIGHT-EMITTING DEVICE

(71) Applicant: BOE Technology Group Co., Ltd., Beijing (CN)

(72) Inventors: Dejiang ZHAO, Beijing (CN); Yang LI, Beijing (CN); Wei HUANG, Beijing (CN); Tianhao LU, Beijing (CN)

(21) Appl. No.: 18/687,577

(22) PCT Filed: Oct. 26, 2021
(86) PCT No.: PCT/CN2021/126340

§ 371 Date: Feb. 28, 2024

(51) Int. Cl. H10K 50/115; H10K 59/12; H10K 59/122; H10K 101/40

(52) U.S. Cl. CPC H10K 50/115; H10K 59/1201; H10K 59/122; H10K 2101/40

(57) ABSTRACT

Disclosed are a light-emitting device, a display panel, a display apparatus and a method for manufacturing a light-emitting device. The light-emitting device includes a first film layer, a light-emitting structure, and a second electrode layer. Where the first film layer includes a middle portion, and an edge portion surrounding the middle portion; the light-emitting structure includes an organic light-emitting layer and a flat portion, the flat portion is located in a region where a smaller one of the first distance and the second distance is located, and the flat portion matches with a contact film layer in energy level, so that after being filled with the flat portion, a film thickness between a surface of the light-emitting structure facing away from the first film layer and the base substrate is consistent.

### CROSS-REFERENCE TO RELATED APPLICATIONS

The application is a National Stage of International Application No. PCT/CN2021/126340, filed Oct. 26, 2021.

### TECHNICAL FIELD

The present disclosure relates to the technical field of semiconductors, in particular to a light-emitting device, a display panel, a display apparatus and a method for manufacturing the light-emitting device.

### BACKGROUND

The quantum dot light emitting diodes (QLED) device structure has the advantages of wide color gamut and low power dissipation, and is regarded as the best structure for the next generation of display devices. QLED devices have two kinds of light-emitting modes, one is a photoluminescent structure, and the other is an electroluminescent structure. The photoluminescent structure is relatively simple, however, scattering particles are contained in materials, the process difficult is large, and a backlight source is needed. The electroluminescent structure is relatively complex, and in addition, the present materials are low in maturity, and device performance is unstable. On the contrary, organic light-emitting diodes (OLEDs) have steadily entered a mass production stage, the efficiency is high, and the color gamut is slightly worse than that of QDs.

### SUMMARY

An embodiment of the present disclosure provides a light-emitting device, including:
a base substrate;
a first electrode layer, arranged on a side of the base substrate;
a first film layer, arranged on a side of the first electrode layer facing away from the base substrate, where the first film layer includes a middle portion, and an edge portion surrounding the middle portion, a surface of the middle portion facing away from the first electrode layer is a first distance from the base substrate, a surface of the edge portion facing away from the first electrode layer is a second distance from the base substrate, and the first distance and the second distance are different;
a light-emitting structure, arranged on a side of the first film layer facing away from the first electrode layer, where the light-emitting structure includes an organic light-emitting layer and a flat portion, the flat portion is located in a region where the smaller one of the first distance and the second distance is located, and the flat portion matches with a contact film layer in energy level, so that after being filled with the flat portion, a film thickness between a surface of the light-emitting structure facing away from the first film layer and the base substrate is consistent; and
a second electrode layer, arranged on a side of the light-emitting structure facing away from the first film layer.

In some embodiments, a material of the flat portion is a quantum dot.

In some embodiments, the first distance is greater than the second distance, and an orthographic projection of the flat portion on the base substrate approximately coincides with an orthographic projection of the edge portion on the base substrate.

In some embodiments, the light-emitting device further includes a first pixel defining layer with a first opening, and a second pixel defining layer with a second opening arranged on a side of the first pixel defining layer facing away from the base substrate, where an orthographic projection of the second opening on the base substrate overlaps at least partially an orthographic projection of the first opening on the base substrate; and
the first pixel defining layer is lyophilic to ethylene glycol, substituted polycyclic aromatic hydrocarbons, diethylene glycol, triethylene glycol dimethyl ether, heptane, methylbenzene, or isopropanol; and the second pixel defining layer is lyophobic to ethylene glycol, substituted polycyclic aromatic hydrocarbons, diethylene glycol, triethylene glycol dimethyl ether, heptane, methylbenzene, or isopropanol.

In some embodiments, the first distance is smaller than the second distance, and the orthographic projection of the flat portion on the base substrate approximately coincides with the orthographic projection of the middle portion on the base substrate.

In some embodiments, the light-emitting device further includes a third pixel defining layer with a third opening; and
the third pixel defining layer is lyophobic to ethylene glycol, substituted polycyclic aromatic hydrocarbons, diethylene glycol, triethylene glycol dimethyl ether, heptane, methylbenzene, or isopropanol; and a film layer in the first film layer in contact with the flat portion is lyophobic to ethylene glycol, substituted polycyclic aromatic hydrocarbons, diethylene glycol, triethylene glycol dimethyl ether, heptane, methylbenzene, or isopropanol.

In some embodiments, the first electrode layer is an anode layer, the second electrode layer is a cathode layer, and the first film layer includes: a hole injection layer, and a hole transport layer arranged on a side of the hole injection layer facing away from the first electrode layer; an electron transport layer is further arranged between the light-emitting structure and the second electrode layer; and
the flat portion is arranged between the hole transport layer and the organic light-emitting layer.

In some embodiments, the first electrode layer is a cathode layer, the second electrode layer is an anode layer, and the first film layer includes: an electron injection layer, and an electron transport layer arranged on a side of the electron injection layer facing away from the first electrode layer; a hole transport layer is further arranged between the light-emitting structure and the second electrode layer; and the flat portion is arranged between the hole transport layer and the organic light-emitting layer.

In some embodiments, a HOMO energy level of the flat portion is located between a HOMO energy level of the hole transport layer and a HOMO energy level of the organic light-emitting layer.

In some embodiments, the HOMO energy level of the flat portion ranges from −5.5 eV to −5.2 eV.

In some embodiments, a material of the flat portion includes one or a combination of the following: CdS; CdSe; CdTe; ZnSe; ZnTe; InP; GaP; InAs; or GaAs.

In some embodiments, the first electrode layer is an anode layer, the second electrode layer is a cathode layer, and the first film layer includes: a hole injection layer, and a hole transport layer arranged on a side of the hole injection layer facing away from the first electrode layer; an electron transport layer is further arranged between the light-emitting structure and the second electrode layer; and
the flat portion is arranged between the electron transport layer and the organic light-emitting layer.

In some embodiments, the first electrode layer is a cathode layer, the second electrode layer is an anode layer, and the first film layer includes: an electron injection layer, and an electron transport layer arranged on a side of the electron injection layer facing away from the first electrode layer; a hole transport layer is further arranged between the light-emitting structure and the second electrode layer; and
the flat portion is arranged between the electron transport layer and the organic light-emitting layer.

In some embodiments, a LUMO energy level of the flat portion is located between a LUMO energy level of the electron transport layer and a LUMO energy level of the organic light-emitting layer.

In some embodiments, the LUMO energy level of the flat portion ranges from −3.3 eV to −2.7 eV.

In some embodiments, a material of the flat portion includes one or a combination of the following: ZnS; ZnTe; or GaP.

In some embodiments, in the same light-emitting device, a light-emitting color of the flat portion is the same as a light-emitting color of the organic light-emitting layer.

In some embodiments, the first electrode layer includes a reflecting material, and at least part of the second electrode layer is a transparent electrode.

An embodiment of the present disclosure further provides a display panel, including the light-emitting device provided by the embodiment of the present disclosure.

An embodiment of the present disclosure further provides a display apparatus, including the display panel provided by embodiments of the present disclosure.

An embodiment of the present disclosure further provides a method for manufacturing a light-emitting device, including:
providing a base substrate;
forming a first electrode layer on a side of the base substrate;
forming a first film layer on a side of the first electrode layer facing away from the base substrate, where the first film layer includes a middle portion, and an edge portion surrounding the middle portion, where a surface of the middle portion facing away from the first electrode layer is a first distance from the base substrate, a surface of the edge portion facing away from the first electrode layer is a second distance from the base substrate, and the first distance and the second distance are different;
forming a light-emitting structure on a side of the first film layer facing away from the first electrode layer, where the light-emitting structure includes an organic light-emitting layer and a flat portion, the flat portion is located in a region where a smaller one of the first distance and the second distance is located, and the flat portion matches a contact film layer in energy level, so that after being filled with the flat portion, a film thickness between a surface of the light-emitting structure facing away from the first film layer and the base substrate is consistent; and
forming a second electrode layer on a side of the light-emitting structure facing away from the first film layer.

In some embodiments, forming the first film layer on at the side of the first electrode layer facing away from the base substrate includes:
printing a first liquid on a side of the first electrode layer facing away from the base substrate through an ink-jet printing process, and drying and shaping the first liquid to form a hole injection layer; and
printing a second liquid on a side of the hole injection layer facing away from the base substrate through the ink-jet printing process, and drying and shaping the second liquid to form a hole transport layer, where the second liquid and the dried and shaped hole injection layer are insoluble to each other.

In some embodiments, printing the first liquid on the side of the first electrode layer facing away from the base substrate includes: printing the first liquid including polystyrene sulfonate on the side of the first electrode layer facing away from the base substrate; and
printing the second liquid on the side of the hole injection layer facing away from the base substrate includes: forming two ethylene groups in N,N′-di(1-naphthyl)-N,N′-diphenyl-1,1′-biphenyl-4-4′-diamine, forming the second liquid through polymerization of the ethylene groups, and printing the second liquid on the side of the hole injection layer facing away from the base substrate.

In some embodiments, forming the light-emitting structure on the side of the first film layer facing away from the first electrode layer includes:
printing a third liquid on a side of the hole transport layer facing away from the hole injection layer through the ink-jet printing process, and drying and shaping the third liquid to form an organic light-emitting layer, where the third liquid and the hole transport layer are insoluble to each other; and
printing a fourth liquid on a side of the organic light-emitting layer facing away from the hole transport layer through the ink-jet printing process, and drying and shaping the fourth liquid to form a flat portion, where the fourth liquid and the dried and shaped organic light-emitting layer are insoluble to each other.

In some embodiments, printing the third liquid on the side of the hole transport layer facing away from the hole injection layer includes: copolymerizing a host emitting body including carbazole and phenylpyridyl with a guest emitting body including tri (2-phenylpyridine) syniridium at a side chain of polyethylene to form the third liquid, and printing the third liquid on the side of the hole transport layer facing away from the hole injection layer; and
printing the fourth liquid on the side of the organic light-emitting layer facing away from the hole transport layer includes: dissolving quantum dots into ethylene glycol to form the fourth liquid, and printing the fourth liquid on the side of the organic light-emitting layer facing away from the hole transport layer.

### BRIEF DESCRIPTION OF FIGURES

FIG. 1A is a first schematic structural diagram of a light-emitting device provided by an embodiment of the present disclosure.

FIG. 1B is a schematic diagram of a part of film layer in FIG. 1A.

FIG. 2A is a second schematic structural diagram of a light-emitting device provided by an embodiment of the present disclosure.

FIG. 2B is a schematic diagram of a part of film layer in FIG. 2A.

FIG. 3A is a third schematic structural diagram of a light-emitting device provided by an embodiment of the present disclosure.

FIG. 3B is a schematic diagram of a part of film layer in FIG. 3A.

FIG. 4A is a fourth schematic structural diagram of a light-emitting device provided by an embodiment of the present disclosure.

FIG. 4B is a schematic diagram of a part of film layer in FIG. 4A.

FIG. 5A is a fifth schematic structural diagram of a light-emitting device provided by an embodiment of the present disclosure.

FIG. 5B is a schematic diagram of a part of film layer in FIG. 5A.

FIG. 6A is a sixth schematic structural diagram of a light-emitting device provided by an embodiment of the present disclosure.

FIG. 6B is a schematic diagram of a part of film layer in FIG. 6A.

FIG. 7A is a seventh schematic structural diagram of a light-emitting device provided by an embodiment of the present disclosure.

FIG. 7B is a schematic diagram of a part of film layer in FIG. 7A.

FIG. 8A is an eighth schematic structural diagram of a light-emitting device provided by an embodiment of the present disclosure.

FIG. 8B is a schematic diagram of a part of film layer in FIG. 8A.

FIG. 9 is a ninth schematic structural diagram of a light-emitting device provided by an embodiment of the present disclosure.

FIG. 10 is a tenth schematic structural diagram of a light-emitting device provided by an embodiment of the present disclosure.

FIG. 11 is an eleventh schematic structural diagram of a light-emitting device provided by an embodiment of the present disclosure.

FIG. 12 is a twelfth schematic structural diagram of a light-emitting device provided by an embodiment of the present disclosure.

FIG. 13 is a contrast diagram of performance of different light-emitting devices.

FIG. 14 is a first schematic flowchart of manufacturing of a light-emitting device provided by an embodiment of the present disclosure.

FIG. 15 is a second schematic flowchart of manufacturing of a light-emitting device provided by an embodiment of the present disclosure.

### DETAILED DESCRIPTION

In order to make objectives, technical solutions and advantages of embodiments of the present disclosure clearer, the technical solutions of embodiments of the present disclosure will be described clearly and integrally below with reference to accompanying drawings of embodiments of the present disclosure. Apparently, the described embodiments are part of embodiments of the present disclosure, not all embodiments. Based on the described embodiments of the present disclosure, all other embodiments obtained by those ordinarily skilled in the art without creative labor belong to the protection scope of the present disclosure.

Unless otherwise defined, technical terms or scientific terms used in the present disclosure should have the ordinary meaning as understood by those of ordinary skill in the art to which the present disclosure pertains. “First”, “second” and similar words used in the present disclosure do not represent any order, quantity or importance, and are only used to distinguish different constituent parts. “Include” or “comprise” and similar words mean that the elements or objects appearing before the words cover the elements or objects recited after the words and their equivalents, but do not exclude other elements or objects. The words “connect” or “link” or the like are not limited to physical or mechanical connection, but may include electrical connection, whether direct or indirect. “Up”, “down”, “left”, “right” and the like are only used to represent a relative position relationship, and after an absolute position of a described object is changed, the relative position relationship may also be changed accordingly.

In order to keep the following description of embodiments of the present disclosure clear and concise, detailed description of known functions and known components is omitted in the present disclosure.

As for OLED light-emitting devices formed by a solution method, especially top-emitting OLED devices, due to the impact of materials and process parameters, film thicknesses of a middle region and an edge region will be caused inconsistent, then microcavity lengths of the middle region and the edge region will be caused inconsistent, and light-emitting colors of the middle region and the edge region are inconsistent. Since a thickness of a material of a hole injection layer is generally between 1000 angstroms and 2000 angstroms, the thickness is much greater than that of materials of a hole transport layer and a light-emitting layer, and a film thickness gap between the edge region and the middle region is greater, the problem is more serious for the structure of the forward top-emitting device.

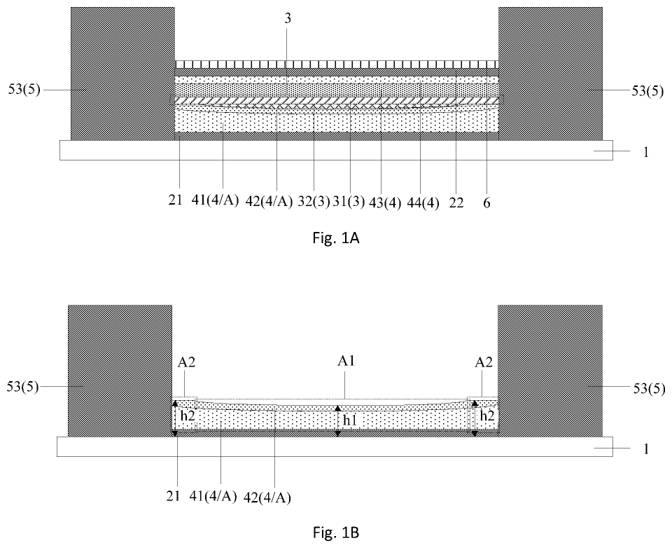

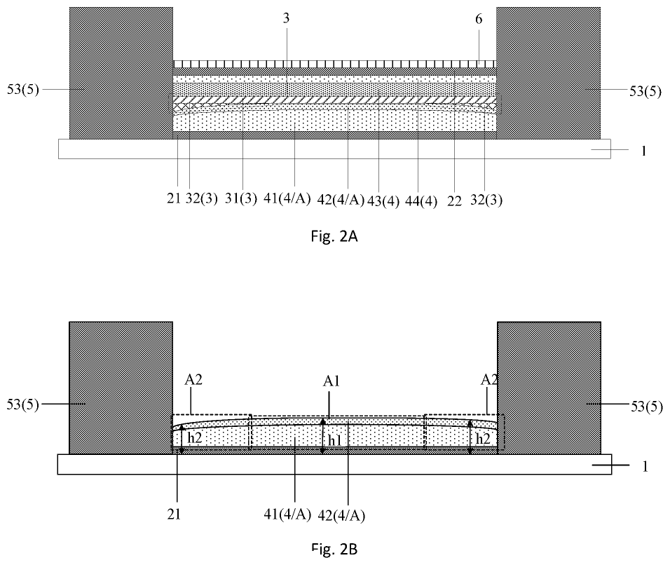

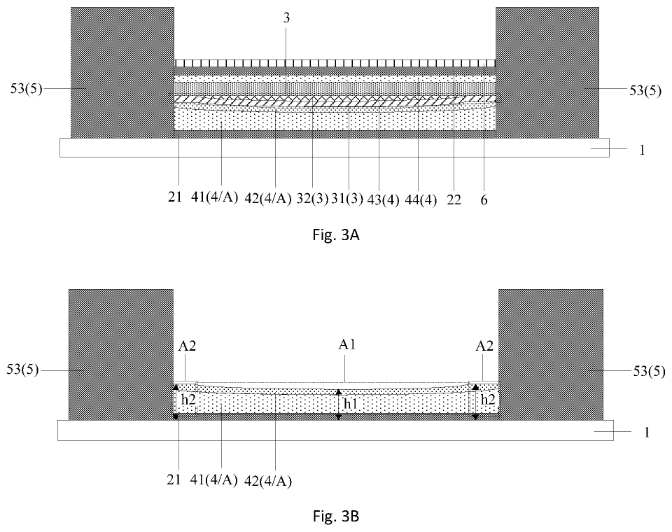

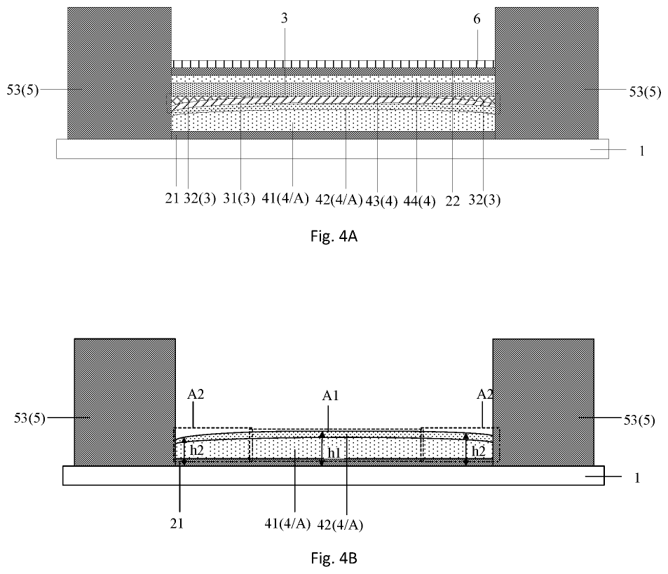

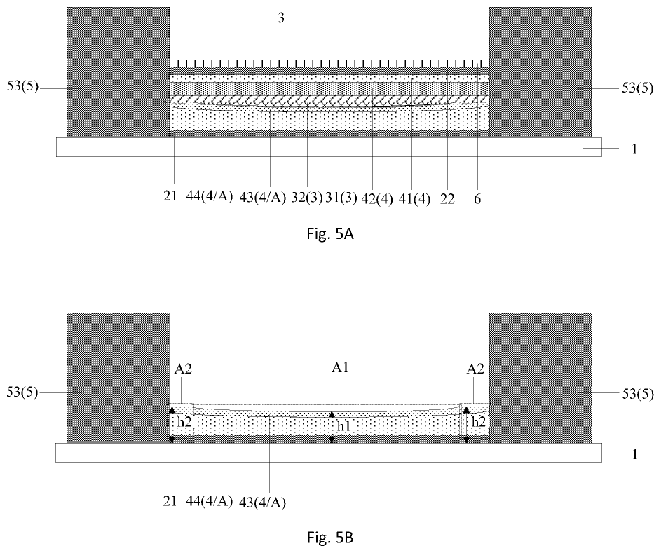

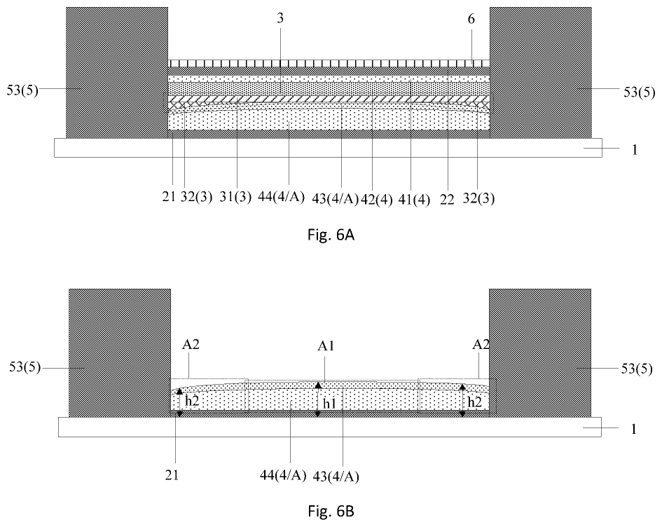

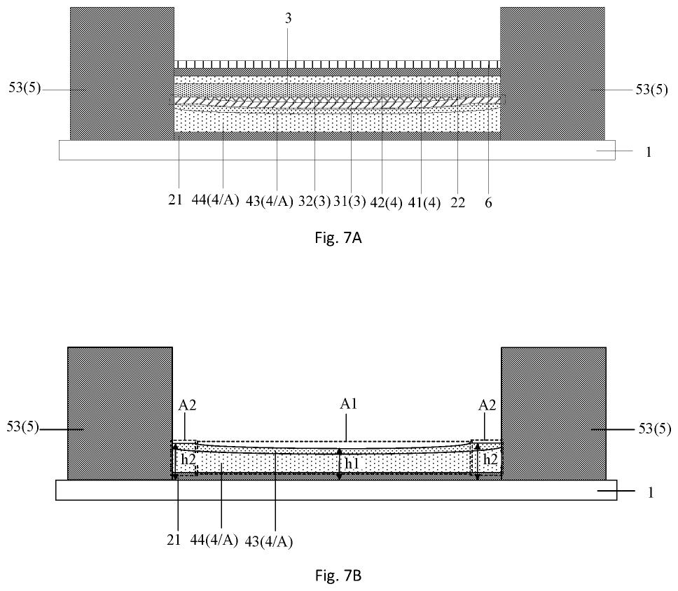

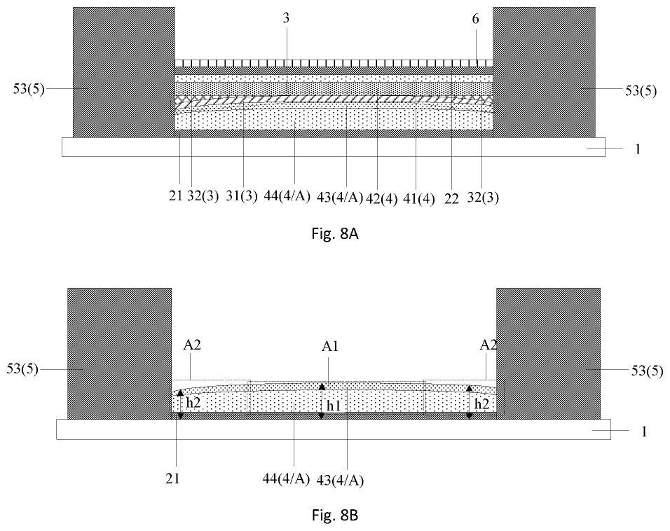

Referring to FIG. 1A, FIG. 1B, FIG. 2A, FIG. 2B, FIG. 3A, FIG. 3B, FIG. 4A, FIG. 4B, FIG. 5A, FIG. 5B, FIG. 6A, FIG. 6B, FIG. 7A, FIG. 7B, FIG. 8A, and FIG. 8B, embodiments of the present disclosure provides a light-emitting device, including:
a base substrate 1;
a first electrode layer 21, arranged on a side of the base substrate 1;
a first film layer A, arranged on a side of the first electrode layer 21 facing away from the base substrate 1, where the first film layer A includes a middle portion A1, and an edge portion A2 surrounding the middle portion A1, where a surface of the middle portion A1 facing away from the first electrode layer 21 is a first distance h1 from the base substrate 1, a surface of the edge portion A2 facing away from the first electrode layer 21 is a second distance h2 from the base substrate 1, and the first distance h1 and the second distance h2 are different;
a light-emitting structure 3, arranged on a side of the first film layer A facing away from the first electrode layer 21, where the light-emitting structure includes an organic light-emitting layer 31 and a flat portion 32, the flat portion 32 is located in a region where the smaller one of the first distance h1 and the second distance h2 is located, and the flat portion matches with a contact film layer in energy level, so that after being filled with the flat portion 32, a film thickness between a surface of the light-emitting structure 3 facing away from the first film layer A and the base substrate 1 is consistent; and
a second electrode layer 22, arranged on a side of the light-emitting structure 3 facing away from the first film layer A.

In embodiments of the present disclosure, when a film thickness of the first film layer A between the light-emitting structure 3 and the base substrate 1 is inconsistent, the flat portion 32 may be arranged in the light-emitting structure 3 and located in the region where the smaller one of the first distance h1 and the second distance h2 is located, then a film layer between the light-emitting structure 3 and the base substrate 1 is filled up, and the problem that light-emitting colors of a middle region and an edge region are inconsistent due to the fact that microcavity lengths of the middle region and the edge region of a light-emitting device are inconsistent is solved. In addition, the flat portion 32 matches with a contact film layer in energy level, so that the situation that the transmission of carriers in the light-emitting device is affected due to the fact that the flat portion 32 does not match with the contact film layer in energy level may be avoided, and then the problem that the light-emitting efficiency of the light-emitting device is reduced due to the fact that the microcavity lengths are inconsistent is solved.

In some embodiments, the film layers between the light-emitting structure 3 and the first electrode layer 21 may be used as the first film layer A, and the specific film layers included in the first film layer A may be different according to the difference of structures of specific devices, for example, for a forward structure device, as shown in FIG. 1A, FIG. 2A, FIG. 3A, and FIG. 4A, the first electrode layer 21 is an anode layer, a second electrode layer 22 is a cathode layer, the first film layer A may include a hole injection layer 41, and a hole transport layer 42 arranged on a side of the hole injection layer 41 facing away from the first electrode layer 21; and for another example, for an inverted structure device, as shown in FIG. 5A, FIG. 6A, FIG. 7A, and FIG. 8A, the first electrode layer 21 is a cathode layer, the second electrode layer 22 is an anode layer, the first film layer A may include an electron transport layer 43, and an electron injection layer 44 arranged on a side of the electron transport layer 43 facing away from the first electrode layer 21.

In some embodiments, a distance between the surface of the middle portion A1 facing away from the first electrode layer 21 and the base substrate 1 may be gradually changed, or may also be a constant value, a distance between the surface of the edge portion A2 facing away from the first electrode layer 21 and the base substrate 1 may also be gradually changed, or may also be a constant value; after the light-emitting device is formed, the distance between the surface of the middle portion A1 facing away from the first electrode layer 21 and the base substrate 1 may be either always greater than the distance between the surface of the edge portion A2 facing away from the first electrode layer 21 and the base substrate 1, as shown in FIG. 2B and FIG. 4B, or always smaller than the distance between the surface of the edge portion A2 facing away from the first electrode layer 21 and the base substrate 1, as shown in FIG. 1B and FIG. 3B. In some embodiments, an area of an orthographic projection of the middle portion A1 on the base substrate 1 accounts for 10% to 90% of an area of an orthographic projection of the first film layer A on the base substrate 1. In some embodiments, an area of an orthographic projection of the edge portion A2 on the base substrate 1 accounts for 10% to 90% of the area of the orthographic projection of the first film layer A on the base substrate 1. In some embodiments, a sum of the area of the orthographic projection of the middle portion A1 on the base substrate 1 and the area of the orthographic projection of the edge portion A2 on the base substrate 1 is equal to the area of the orthographic projection of the first film layer A on the base substrate 1. In some embodiments, the middle portion A1 and the edge portion A2 may be a relative position.

In some embodiments, the film layers in contact with the flat portion 32 may be different according to the difference of the structures of the specific devices, for example, for the forward structure device, in conjunction with FIG. 1A, the first film layer A includes the hole injection layer 41, and the hole transport layer 42 arranged on the side of the hole injection layer 41 facing away from the first electrode layer 21, and when the flat portion 32 is arranged between the organic light-emitting layer 31 and the hole transport layer 42, the film layers in contact with the flat portion 32 are the hole transport layer 42 and the organic light-emitting layer 31; for another example, for the forward structure device, in conjunction with FIG. 3A, the first film layer A includes the hole injection layer 41, and the hole transport layer 42 arranged on the side of the hole injection layer 41 facing away from the first electrode layer 21, the light-emitting device further includes the electron transport layer 43 arranged on the side of the light-emitting structure facing away from the base substrate 1, and when the flat portion 32 is located between the organic light-emitting layer 31 and the electron transport layer 43, the film layers in contact with the flat portion 32 are the electron transport layer 43 and the organic light-emitting layer 31. In some embodiments, energy level match may be understood as an energy level of the flat portion 32 being between energy levels of two contact film layers, for example, when the flat portion 32 is located between the hole transport layer 42 and the organic light-emitting layer 31, a HOMO energy level of the flat portion 32 needs to be located between a HOMO energy level of the hole transport layer 42 and a HOMO energy level of the organic light-emitting layer 31; and for another example, when the flat portion 32 is located between the electron transport layer 43 and the organic light-emitting layer 31, a LUMO energy level of the flat portion 32 needs to be located between a LUMO energy level of the electron transport layer 43 and a LUMO energy level of the organic light-emitting layer 31.

In some embodiments, due to the limitation of the actual process, the film thickness between the surface of the light-emitting structure 3 facing away from the first film layer A and the base substrate 1 is required to be absolutely consistent, which is difficult to achieve, and therefore, the film thickness between the surface of the light-emitting structure 3 facing away from the first film layer A and the base substrate 1 is consistent, which may be understood to be that a difference value between the maximum film thickness between the surface of the light-emitting structure 3 facing away from the first film layer A and the base substrate 1 and the minimum film thickness between the surface of the light-emitting structure 3 facing away from the first film layer A and the base substrate 1 ranges from 0 nm to 10 nm.

In some embodiments, a material of the flat portion 32 may be an electroluminescent material. In some embodiments, the material of the flat portion 32 is a quantum dot. In the embodiment of the present disclosure, the material of the flat portion 32 is the quantum dot, a quantum dot layer may serve as a carrier barrier layer, for example, the quantum dot layer may serve as an electron barrier layer when being located between the hole transport layer and the organic light-emitting layer, and may block electrons from the cathode layer at the light-emitting layer, thereby improving the probability of recombining the electrons and holes at the light-emitting layer of the light-emitting device, and the light-emitting efficiency of the light-emitting device is improved; for another example, when being located between the electron transport layer and the organic light-emitting layer, the quantum dot layer may serve as a hole barrier layer, and may block holes from the anode layer at the light-emitting layer, thereby improving the probability of recombining the electrons and holes at the light-emitting layer of the light-emitting device, and improving the light-emitting efficiency of the light-emitting device; and in addition, the quantum dot layer may also play a certain function of exciton transfer, that is, the holes and the electrons are recombined at the organic light-emitting layer 31 to form excitons, since the flat portion 32 and the organic light-emitting layer 31 of the quantum dot material are cross-distributed at an interface, these excitons are transmitted to the flat portion 32 instead of radiating and emitting light directly, and radiate and emit light through the flat portion 32 of the quantum dot material, the light-emitting color purity of the flat portion 32 of the quantum dot material is high, and when the light-emitting device is applied to a display field, a color gamut of a display panel may be expanded.

In some embodiments, referring to FIG. 2A, FIG. 2B, FIG. 4A, FIG. 4B, FIG. 6A, FIG. 6B, FIG. 8A and FIG. 8B, the first distance h1 is greater than the second distance h2, an orthographic projection of the flat portion 32 on the base substrate 1 approximately coincides with an orthographic projection of the edge portion A2 on the base substrate 1, and thus, the problem that microcavity lengths of the middle region and the edge region of the light-emitting device are inconsistent caused by the small film thickness of the edge portion A2 of the first film layer A1, and consequently, light-emitting colors of the middle region and the edge region are inconsistent is solved. In some embodiments, the orthographic projection of the flat portion 32 on the base substrate 1 approximately coincides with the orthographic projection of the edge portion A2 on the base substrate 1, which may be understood that areas of the orthographic projections of the two coincide by 80% to 100%.

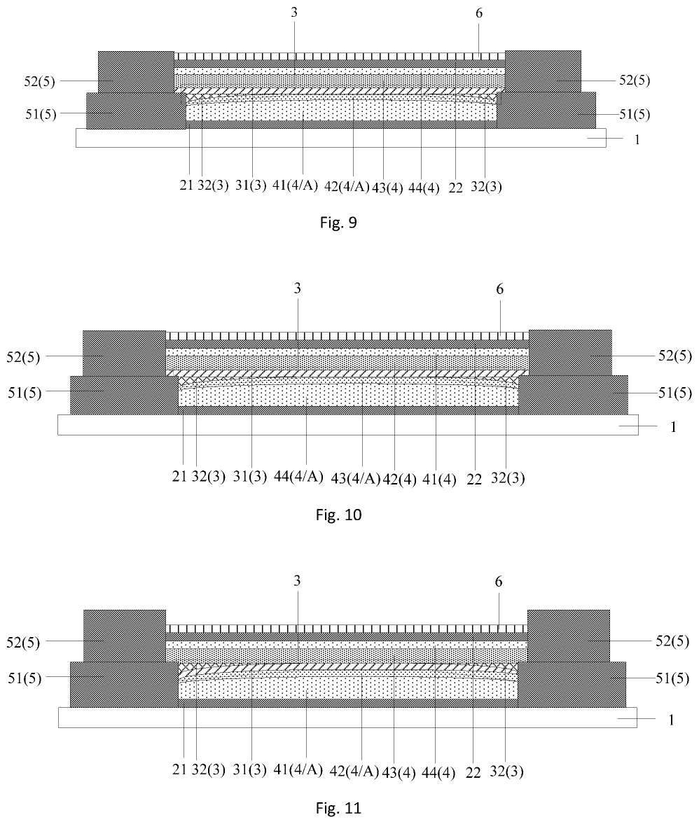

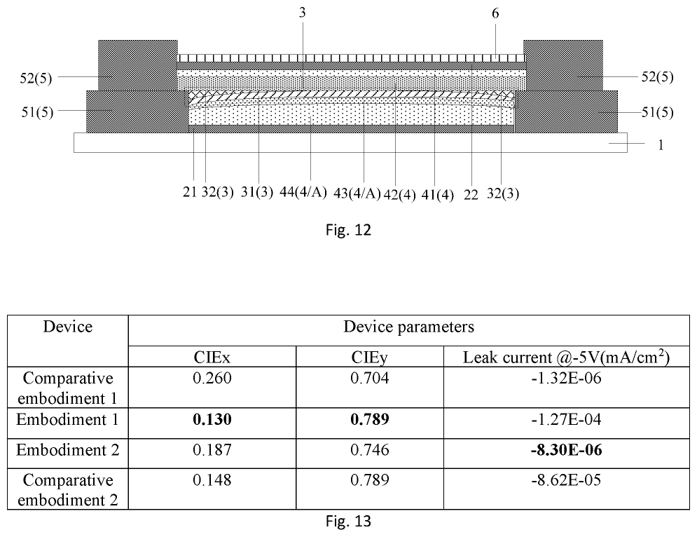

In some embodiments, the light-emitting device may include a pixel defining layer 5, the pixel defining layer 5 may be of a single layer structure or a double-layer structure. In some embodiments, referring to FIG. 9, FIG. 10, FIG. 11, and FIG. 12, when the orthographic projection of the flat portion 32 on the base substrate 1 approximately coincides with the orthographic projection of the edge portion A2 on the base substrate 1, the light-emitting device may include a double-layer pixel defining layer, the double-layer pixel defining layer is a first pixel defining layer 51 with a first opening, and a second pixel defining layer 52 with a second opening arranged on a side of the first pixel defining layer 51 facing away from the base substrate 1, and an orthographic projection of the second opening on the base substrate 1 at least partially overlaps an orthographic projection of the first opening on the base substrate 1; the first pixel defining layer 51 is lyophilic to ethylene glycol, substituted polycyclic aromatic hydrocarbons, diethylene glycol, triethylene glycol dimethyl ether, heptane, methylbenzene, or isopropanol; and the second pixel defining layer is lyophobic to ethylene glycol, substituted polycyclic aromatic hydrocarbons, diethylene glycol, triethylene glycol dimethyl ether, heptane, methylbenzene, or isopropanol. In the embodiment of the present disclosure, ethylene glycol, substituted polycyclic aromatic hydrocarbons, diethylene glycol, triethylene glycol dimethyl ether, heptane, methylbenzene, or isopropanol may be a solvent for forming the flat portion 32 of the quantum dot material, a thickness of the middle portion A1 of the first film layer A is greater than a thickness of the edge portion A2, when the flat portion 32 needs to be arranged at a region where the edge portion A2 is located, the double-layer pixel defining layer may be arranged, so that the first pixel defining layer 51 is lyophilic to a quantum dot solvent, the second pixel defining layer 52 is lyophobic to the quantum dot solvent, then when the solvent containing the quantum dots is printed and dried in the light-emitting device, the first pixel defining layer 51 attracts the quantum dot solvent, the second pixel defining layer 52 repels the quantum dot solvent, and finally, the quantum dots are formed in the region where the edge portion A2 with the small thickness is located, thereby solving the problem that the light-emitting colors of the light-emitting device are inconsistent due to the edge region.

In some embodiments, in conjunction with FIG. 1A, FIG. 1B, FIG. 3A, FIG. 3B, FIG. 5A, FIG. 5B, FIG. 7A, and FIG. 7B, the first distance h1 is smaller than the second distance h2, the orthographic projection of the flat portion 32 on the base substrate 1 approximately coincides with the orthographic projection of the middle portion A1 on the base substrate 1, and thus, the problem that microcavity lengths of the middle region and the edge region of the light-emitting device are inconsistent caused by the small film thickness of the middle portion A1 of the first film layer A, and consequently, light-emitting colors of the middle region and the edge region are inconsistent is solved. In some embodiments, the orthographic projection of the flat portion 32 on the base substrate 1 approximately coincides with the orthographic projection of the middle portion A1 on the base substrate 1, which may be understood that areas of the orthographic projections of the two coincide by 80% to 100%.

In some embodiments, when the orthographic projection of the flat portion 32 on the base substrate 1 approximately coincides with the orthographic projection of the middle portion A1 on the base substrate 1, the light-emitting device further includes a third pixel defining layer 53 having a third opening; the third pixel defining layer 53 is lyophobic to ethylene glycol, substituted polycyclic aromatic hydrocarbons, diethylene glycol, triethylene glycol dimethyl ether, heptane, methylbenzene, or isopropanol; and a film layer in the first film layer A in contact with the flat portion 32 is lyophobic to ethylene glycol, substituted polycyclic aromatic hydrocarbons, diethylene glycol, triethylene glycol dimethyl ether, heptane, methylbenzene, or isopropanol. In the embodiment of the present disclosure, ethylene glycol, substituted polycyclic aromatic hydrocarbons, diethylene glycol, triethylene glycol dimethyl ether, heptane, methylbenzene, or isopropanol may be a solvent for forming the flat portion 32 of the quantum dot material, the thickness of the middle portion A1 of the first film layer A is smaller than the thickness of the edge portion A2, when the flat portion 32 needs to be arranged at a region where the middle portion A1 is located, a single layer pixel defining layer may be arranged, so that the third pixel defining layer 53, as a single layer, is lyophobic to the quantum dot solvent, the film layer in the first film layer A in contact with the flat portion 32 is lyophobic to the quantum dot solvent, that is, since positions of the quantum dots are mainly affected by the pixel defining layers, secondly affected by the film layer below the quantum dot film layer in contact with it, when the flat portion 32 of the quantum dot material needs to be located in the middle region, the third pixel defining layer 53 may be lyophobic to the quantum dot solvent, then the quantum dots are repelled into the middle region, so the film layer in the first film layer A in contact with the flat portion 32 is lyophobic to the quantum dot solvent, the flat portion 32 of the quantum dot material cannot be extended on the film layer below, the flat portion covers the middle region after being dried, and finally, the flat portion 32 of the quantum dot material is formed in the region where the middle portion A1 with the small thickness is located, thereby solving the problem that the light-emitting colors of the light-emitting device are inconsistent due to the edge region.

The position of the flat portion 32 is illustrated with reference to a light-emitting device structure, as follows.

For example, the light-emitting device is a forward structure, referring to FIG. 1A and FIG. 2A, FIG. 1A is a schematic diagram of a thickness of the middle portion A1 being smaller than a thickness of the edge portion A2 of the first film layer A, FIG. 2A is a schematic diagram of the thickness of the middle portion A1 being greater than the thickness of the edge portion A2 of the first film layer A, the first electrode layer 21 is the anode layer, the second electrode layer 22 is the cathode layer, and the first film layer A includes: the hole injection layer 41, and the hole transport layer 42 arranged on the side of the hole injection layer 41 facing away from the first electrode layer 21; the electron transport layer 43 is further arranged between the light-emitting structure 3 and the second electrode layer 22, and the electron injection layer 44 is further arranged between the electron transport layer 43 and the second electrode layer 22; and the flat portion 32 is arranged between the hole transport layer 42 and the organic light-emitting layer 31.

For another example, the light-emitting device is an inverted structure, referring to FIG. 7A and FIG. 8A, FIG. 7A is a schematic diagram of the thickness of the middle portion A1 being smaller than the thickness of the edge portion A2 of the first film layer A, FIG. 8A is a schematic diagram of the thickness of the middle portion A1 being greater than the thickness of the edge portion A2 of the first film layer A, the first electrode layer 21 is the cathode layer, the second electrode layer 22 is the anode layer, and the first film layer A includes: the electron injection layer 44, and the electron transport layer 43 arranged on the side of the electron injection layer 44 facing away from the first electrode layer 21; the hole transport layer 42 is further arranged between the light-emitting structure 3 and the second electrode layer 22; and the flat portion 32 is arranged between the hole transport layer 42 and the organic light-emitting layer 31.

In some embodiments, when the flat portion 32 is located between the hole transport layer 42 and the organic light-emitting layer 31, the HOMO energy level of the flat portion is located between the HOMO energy level of the hole transport layer 42 and the HOMO energy level of the organic light-emitting layer 31, so that the energy level of the flat portion 32 matches with energy levels of the hole transport layer 42 and the organic light-emitting layer 31 which are in contact with it. In some embodiments, the HOMO energy level of the flat portion 32 ranges from −5.5 eV to −5.2 eV, and therefore, the energy level match with the general hole transport layer 42 and the organic light-emitting layer 31 is achieved.

In some embodiments, the material of the flat portion 32 includes one or a combination of the following: CdS; CdSe; CdTe; ZnSe; ZnTe; InP; GaP; InAs; or GaAs. Therefore, the energy level match with the general hole transport layer 42 and the organic light-emitting layer 31 is achieved.

For example, the light-emitting device is the forward structure, referring to FIG. 3A and FIG. 4A, FIG. 3A is a schematic diagram of the thickness of the middle portion A1 being smaller than the thickness of the edge portion A2 of the first film layer A, FIG. 4A is a schematic diagram of the thickness of the middle portion A1 being greater than the thickness of the edge portion A2 of the first film layer A, the first electrode layer 21 is the anode layer, the second electrode layer 22 is the cathode layer, and the first film layer A includes: the hole injection layer 41, and the hole transport layer 42 arranged on the side of the hole injection layer 41 facing away from the first electrode layer 21; the electron transport layer 43 is further arranged between the light-emitting structure 3 and the second electrode layer 22, and the electron injection layer 44 is further arranged between the electron transport layer 43 and the second electrode layer 22; and the flat portion 32 is arranged between the electron transport layer 43 and the organic light-emitting layer 31.

For another example, the light-emitting device is the inverted structure, referring to FIG. 5A and FIG. 6A, FIG. 5A is a schematic diagram of the thickness of the middle portion A1 being smaller than the thickness of the edge portion A2 of the first film layer A, FIG. 6A is a schematic diagram of the thickness of the middle portion A1 being greater than the thickness of the edge portion A2 of the first film layer A, the first electrode layer 21 is the cathode layer, the second electrode layer 22 is the anode layer, and the first film layer A includes: the electron injection layer 44, and the electron transport layer 43 arranged on the side of the electron injection layer 44 facing away from the first electrode layer 21; the hole transport layer 42 is further arranged between the light-emitting structure 3 and the second electrode layer 22, and the hole injection layer 41 may be further arranged between the hole transport layer 42 and the second electrode layer 22; and the flat portion 32 is arranged between the electron transport layer 43 and the organic light-emitting layer 31.

In some embodiments, the flat portion 32 is located between the electron transport layer 43 and the organic light-emitting layer 31, and the LUMO energy level of the flat portion 32 is located between the LUMO energy level of the electron transport layer 43 and the LUMO energy level of the organic light-emitting layer 31, so that the energy level of the flat portion 32 matches with the energy levels of the electron transport layer 43 and the organic light-emitting layer 31 which are in contact with it. In some embodiments, the LUMO energy level of the flat portion ranges from −3.3 eV to −2.7 eV, and therefore, the energy level match with the general electron transport layer 43 and the organic light-emitting layer 31 is achieved.

In some embodiments, the material of the flat portion 32 includes one or a combination of the following: ZnS; ZnTe; or GaP. Therefore, the energy level match with the general electron transport layer 43 and the organic light-emitting layer 31 is achieved.

In some embodiments, in the same light-emitting device, the light-emitting color of the flat portion 32 is the same as the light-emitting color of the organic light-emitting layer 31.

In some embodiments, in terms of material selection, the quantum dot material, the hole transport layer 42 and the organic light-emitting layer 31 are required to make the cross section of the material keep orthogonal, that is, ink of quantum dots cannot dissolve the hole transport layer 42 and the organic light-emitting layer 31, ink forming the organic light-emitting layer 31 cannot dissolve the flat portion 32 of the quantum dot material, and the thickness of the flat portion 32 of the quantum dot material ranges from 10 nm to 20 nm, which avoid increased lighting voltage caused by excessive film layer thickness.

In some embodiments, for the flat portion 32, a completed film layer migration rate is at 10⁻⁴m/s.

In some embodiments, the hole transport layer 42 may include arylamine or N,N′-di(1-naphthyl)-N,N′-diphenyl-1,1′-biphenyl-4-4′-diamine; and the flat portion 32 may include a dimethyl phenyl ligand. The quantum dot material generally cannot be manufactured through evaporation, and will adopt a solution way, and a mutual dissolution problem will exist by adopting a solution manufacturing process (such as adopting ink-jet printing). In the embodiment of the present disclosure, the hole transport layer 42 includes arylamine or N,N′-di(1-naphthyl)-N,N′-diphenyl-1,1′-biphenyl-4-4′-diamine; and the flat portion 32 includes the dimethyl phenyl ligand, and the problem of low manufacturing success rate of the light-emitting device caused by the fact that when manufacturing of the hole transport layer is completed, the subsequently manufactured flat portion 32 will dissolve the hole transport layer manufactured before may be solved.

In some embodiments, the electron transport layer 43 includes zinc oxide, titanium dioxide, and selenium dioxide; and a solvent forming the flat portion 32 includes methanol series, ethylene glycol series, benzyl series or ethanolamine. Thus, when the flat portion 32 of the quantum dot material is formed after the electron transport layer 43, the electron transport layer 43 will not be dissolved.

In some embodiments, when the hole injection layer 41 and the hole transport layer 42 are manufactured, an orthogonal (after being baked and shaped, the film layer will not be dissolved by the later layer of solvent) material may further be adopted.

In some embodiments, the first electrode layer 21 may be a transparent electrode layer, and the second electrode layer 22 may be a reflected electrode layer; or, the first electrode layer 21 may be a reflected electrode layer, and the second electrode layer 22 may be a transparent electrode layer. In some embodiments, for example, when the first electrode layer 21 is the transparent electrode layer, and the second electrode layer 22 is the reflected electrode layer, the light-emitting device may achieve bottom emission. In some embodiments, a material of the first electrode layer 21 may be indium tin oxide, and a material of the second electrode layer 22 may be aluminum and/or silver.

In some embodiments, the first electrode layer 21 includes a reflecting material, and the second electrode layer 22 is at least partially electrode-transparent. In some embodiments, the second electrode layer 22 may be a transparent electrode layer, that is, when the first electrode layer 21 may be the reflected electrode layer, and the second electrode layer 22 may be the transparent electrode layer, the light-emitting device may achieve top emission. In some embodiments, the material of the first electrode layer 21 may include indium tin oxide, silver, and indium tin oxide which are arranged in a laminated mode, and the material of the second electrode layer 22 may include silver and magnesium which are arranged in a laminated mode.

For a top-emission OLED device structure formed through a solution method, due to the impact of materials and process parameters, film thicknesses of the middle region and the edge region will be inconsistent, then microcavity lengths of the middle region and the edge region will be inconsistent, the light-emitting colors of the middle region and the edge region will be inconsistent, since a thickness of the hole injection layer 41 generally ranges from 1000 angstroms to 2000 angstroms, the thickness is further greater than a thickness of the hole transport layer 42 and a thickness of the organic light-emitting layer 31, and a film thickness gap of the edge region and the middle region is greater, which is more series for the forward top-emitting device structure. According to the embodiments of the present disclosure, the flat portion 32 fills up a film layer between the light-emitting structure 3 and the base substrate 1, so that it has a good effect on solving the problem of inconsistent light-emitting colors caused by the inconsistence of the microcavity lengths of the forward top-emitting device.

In some embodiments, the anode layer may adopt an ITO/Ag/ITO structure, the thicknesses may be respectively 10 nm/100 nm/10 nm, the thickness of the hole injection layer 41 may be designed according to different cavity lengths, according to different colors, a selecting range ranges from 20 nm to 200 nm, and the hole transport layer 42 generally ranges from 20 nm to 30 nm; a total thickness of the hole injection layer 41 and the hole transport layer 42 is used for making an optical adjusting layer, and a length range of the thickness ranges from 20 nm to 200 nm; a general thickness of the electron transport layer 43 may range from 30 nm to 60 nm, and a red light-emitting device may be longer up to 90 nm; a thickness of the quantum dot layer may range from 10 nm to 20 nm; the thickness of the electron transport layer 43 may range from 30 nm to 50 nm; an thickness of the electron injection layer (EIL) may range from 0.5 nm to 3 nm; and a thickness of the cathode layer may range from 100 nm to 200 nm.

In some embodiments, as shown in FIG. 13, it is a performance contrast diagram of four device structures in a first comparative embodiment, a second comparative embodiment, a first embodiment and a second embodiment, in the first comparative embodiment, an organic light-emitting layer is arranged, in the first embodiment, the organic light-emitting layer 31 and the flat portion 32 are arranged, the flat portion 32 is arranged on the side of the organic light-emitting layer 31 facing away from the base substrate, in the second embodiment, an organic light-emitting layer GB and a quantum dot layer QD are arranged, the quantum dot layer QD is arranged on the side of the organic light-emitting layer 31 facing the base substrate, in the second comparative embodiment, a quantum dot layer QD is arranged. In some embodiments, in the first comparative embodiment, the second comparative embodiment, the first embodiment and the second embodiment, other film layers may further be arranged, and in addition to the organic light-emitting layer and the quantum dot layer, other film layers in the second comparative embodiment, the first embodiment and the second embodiment are the same. It may be known from FIG. 10B that compared with the first comparative embodiment, a chromaticity coordinate y(CIEy) of the first embodiment is increased, a chromaticity coordinate x (CIEx) is decreased, and a color gamut range is larger; and compared with the second comparative embodiment, a leak current at −5V is −8.62E−05 mA/cm², a leak current of the second embodiment at −5V is −8.30E−06 mA/cm², which is obviously reduced, the leak current problem is solved, and the efficiency is obviously improved.

The material of the organic light-emitting layer 31 may be an organic small molecule material or a polymer material crosslinked.

In some embodiments, the display panel may further include a light extracting layer 6 arranged on a side of the second electrode layer 22 facing away from the first electrode layer 21.

Embodiments of the present disclosure further provide a display panel, including a plurality of light-emitting devices provided by embodiments of the present disclosure.

In some embodiments, the plurality of light-emitting devices include red light-emitting devices, green light-emitting devices and blue light-emitting devices.

Embodiments of the present disclosure further provide a display apparatus, including the display panel provided by embodiments of the present disclosure.

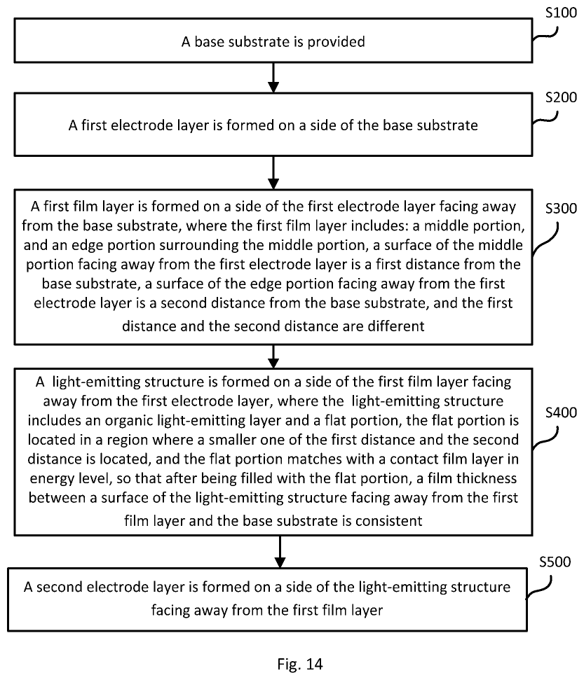

Embodiments of the present disclosure further provide a method for manufacturing a display panel, referring to FIG. 14, the display panel has a plurality of light-emitting devices, the manufacturing method includes:
step S100, a base substrate is provided;
step S200, a first electrode layer is formed on a side of the base substrate;
step S300, a first film layer is formed on a side of the first electrode layer facing away from the base substrate, where the first film layer includes: a middle portion, and an edge portion surrounding the middle portion, a surface of the middle portion facing away from the first electrode layer is a first distance from the base substrate, a surface of the edge portion facing away from the first electrode layer is a second distance from the base substrate, and the first distance and the second distance are different;
step S400, a light-emitting structure is formed on a side of the first film layer facing away from the first electrode layer, where the light-emitting structure includes an organic light-emitting layer and a flat portion, the flat portion is located in a region where a smaller one of the first distance and the second distance is located, and the flat portion matches with a contact film layer in energy level, so that after being filled with the flat portion, a film thickness between a surface of the light-emitting structure facing away from the first film layer and the base substrate is consistent; and
step S500, a second electrode layer is formed on a side of the light-emitting structure facing away from the first film layer.

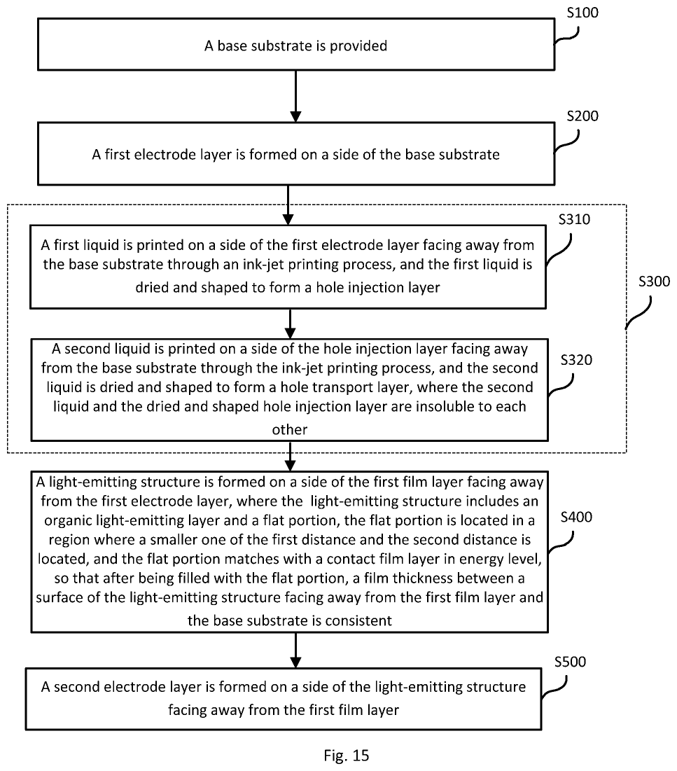

In some embodiments, the light-emitting device may be a forward device structure, the first electrode layer may be an anode layer, and the second electrode layer may be a cathode layer. Referring to FIG. 15, for the step S300, forming the first film layer on the side of the first electrode layer facing away from the base substrate may include:
step S310, a first liquid is printed on a side of the first electrode layer facing away from the base substrate through an ink-jet printing process, and the first liquid is dried and shaped to form a hole injection layer; where the printing the first liquid on the side of the first electrode layer facing away from the base substrate may include: the first liquid including polystyrene sulfonate is printed on the side of the first electrode layer facing away from the base substrate; and
step S320, a second liquid is printed on a side of the hole injection layer facing away from the base substrate through the ink-jet printing process, and the second liquid is dried and shaped to form a hole transport layer, where the second liquid and the dried and shaped hole injection layer are insoluble to each other; where the printing the second liquid on the side of the hole injection layer facing away from the base substrate may include: two ethylene groups are formed at N,N′-di(1-naphthyl)-N,N′-diphenyl-1,1′-biphenyl-4-4′-diamine, the second liquid is formed through polymerization of the ethylene groups, and the second liquid is printed on the side of the hole injection layer facing away from the base substrate.

In some embodiments, for the step S400, forming the light-emitting structure on the side of the first film layer facing away from the first electrode layer includes:
step S410, a third liquid is printed on a side of the hole transport layer facing away from the hole injection layer through the ink-jet printing process, and the third liquid is dried and shaped to form the organic light-emitting layer, where the third liquid and the hole transport layer are insoluble to each other; where the printing the third liquid on the side of the hole transport layer facing away from the hole injection layer may include: a host emitting body including carbazole and phenylpyridyl is copolymerized with a guest emitting body including tri (2-phenylpyridine) syniridium at a side chain of polyethylene to form the third liquid, and the third liquid is printed on the side of the hole transport layer facing away from the hole injection layer; and
step S420, a fourth liquid is printed on a side of the organic light-emitting layer facing away from the hole transport layer through the ink-jet printing process, and the fourth liquid is dried and shaped to form a quantum dot layer, where the fourth liquid and the dried and shaped organic light-emitting layer are insoluble to each other; where the printing the fourth liquid on the side of the organic light-emitting layer facing away from the hole transport layer may include: quantum dots are dissolved into ethylene glycol to form the fourth liquid, and the fourth liquid is printed on the side of the organic light-emitting layer facing away from the hole transport layer.

Those skilled in the art should understand that embodiments of the present disclosure may be provided as a method, a system, or a computer program product. Therefore, the present disclosure may adopt a form of a complete hardware embodiment, a complete software embodiment, or an embodiment combining software and hardware aspects. In addition, the present disclosure may adopt the form of the computer program product implemented on one or more computer usable storage media (including but not limited to a disk memory, a CD-ROM, an optical memory, etc.) including computer usable program codes.

Although the preferred embodiments of the present disclosure have been described, those skilled in the art can make additional alterations and modifications on these embodiments once they know the basic creative concept. Therefore, the appended claims intend to be explained as including the preferred embodiments and all alterations and modifications falling within the scope of the present disclosure.

Obviously, those skilled in the art can make various modifications and variations to embodiments of the present disclosure without departing from the spirit and scope of embodiments of the present disclosure. In this way, if these modifications and variations of embodiments of the present disclosure fall within the scope of the claims of the present disclosure and their equivalent art, the present disclosure also intends to include these modifications and variations.

1-25. (canceled)

26. A light-emitting device, comprising:
a base substrate;
a first electrode layer, arranged on a side of the base substrate;
a first film layer, arranged on a side of the first electrode layer facing away from the base substrate, wherein the first film layer comprises a middle portion, and an edge portion surrounding the middle portion; a surface of the middle portion facing away from the first electrode layer is a first distance from the base substrate, a surface of the edge portion facing away from the first electrode layer is a second distance from the base substrate, and the first distance and the second distance are different;
a light-emitting structure, arranged on a side of the first film layer facing away from the first electrode layer, wherein the light-emitting structure comprises an organic light-emitting layer and a flat portion, the flat portion is located in a region where a smaller one of the first distance and the second distance is located, and the flat portion matches with a contact film layer in energy level, so that after being filled with the flat portion, a film thickness between a surface of the light-emitting structure facing away from the first film layer and the base substrate is consistent; and
a second electrode layer, arranged on a side of the light-emitting structure facing away from the first film layer.

27. The light-emitting device according to claim 26, wherein a material of the flat portion is a quantum dot.

28. The light-emitting device according to claim 26, wherein the first distance is greater than the second distance; and
an orthographic projection of the flat portion on the base substrate approximately coincides with an orthographic projection of the edge portion on the base substrate.

29. The light-emitting device according to claim 28, further comprising: a first pixel defining layer with a first opening, and a second pixel defining layer with a second opening arranged on a side of the first pixel defining layer facing away from the base substrate, wherein an orthographic projection of the second opening on the base substrate overlaps at least partially an orthographic projection of the first opening on the base substrate; and
the first pixel defining layer is lyophilic to ethylene glycol, substituted polycyclic aromatic hydrocarbons, diethylene glycol, triethylene glycol dimethyl ether, heptane, methylbenzene, or isopropanol; and the second pixel defining layer is lyophobic to ethylene glycol, substituted polycyclic aromatic hydrocarbons, diethylene glycol, triethylene glycol dimethyl ether, heptane, methylbenzene, or isopropanol.

30. The light-emitting device according to claim 26, wherein the first distance is smaller than the second distance; and
an orthographic projection of the flat portion on the base substrate approximately coincides with an orthographic projection of the middle portion on the base substrate.

31. The light-emitting device according to claim 30, further comprising: a third pixel defining layer with a third opening; wherein
the third pixel defining layer is lyophobic to ethylene glycol, substituted polycyclic aromatic hydrocarbons, diethylene glycol, triethylene glycol dimethyl ether, heptane, methylbenzene, or isopropanol; and
a film layer in the first film layer in contact with the flat portion is lyophobic to ethylene glycol, substituted polycyclic aromatic hydrocarbons, diethylene glycol, triethylene glycol dimethyl ether, heptane, methylbenzene, or isopropanol.

32. The light-emitting device according to claim 26, wherein the first electrode layer is an anode layer, the second electrode layer is a cathode layer, and the first film layer comprises: a hole injection layer, and a hole transport layer arranged on a side of the hole injection layer facing away from the first electrode layer;
an electron transport layer is further arranged between the light-emitting structure and the second electrode layer; and
the flat portion is arranged between the hole transport layer and the organic light-emitting layer.

33. The light-emitting device according to claim 26, wherein the first electrode layer is a cathode layer, the second electrode layer is an anode layer, and the first film layer comprises: an electron injection layer, and an electron transport layer arranged on a side of the electron injection layer facing away from the first electrode layer;
a hole transport layer is further arranged between the light-emitting structure and the second electrode layer; and
the flat portion is arranged between the hole transport layer and the organic light-emitting layer.

34. The light-emitting device according to claim 32, wherein a HOMO energy level of the flat portion is located between a HOMO energy level of the hole transport layer and a HOMO energy level of the organic light-emitting layer.

35. The light-emitting device according to claim 34, wherein the HOMO energy level of the flat portion ranges from −5.5 eV to −5.2 eV.

36. The light-emitting device according to claim 35, wherein a material of the flat portion comprises one or a combination of following:
CdS;
CdSe;
CdTe;
ZnSe;
ZnTe;
InPl
GaP;
InAs; or
GaAs.

37. The light-emitting device according to claim 26, wherein the first electrode layer is an anode layer, the second electrode layer is a cathode layer, and the first film layer comprises: a hole injection layer, and a hole transport layer arranged on a side of the hole injection layer facing away from the first electrode layer;
an electron transport layer is further arranged between the light-emitting structure and the second electrode layer; and
the flat portion is arranged between the electron transport layer and the organic light-emitting layer.

38. The light-emitting device according to claim 26, wherein the first electrode layer is a cathode layer, the second electrode layer is an anode layer, and the first film layer comprises: an electron injection layer, and an electron transport layer arranged on a side of the electron injection layer facing away from the first electrode layer;
a hole transport layer is further arranged between the light-emitting structure and the second electrode layer; and
the flat portion is arranged between the electron transport layer and the organic light-emitting layer.

39. The light-emitting device according to claim 37, wherein a LUMO energy level of the flat portion is located between a LUMO energy level of the electron transport layer and a LUMO energy level of the organic light-emitting layer.

40. The light-emitting device according to claim 39, wherein the LUMO energy level of the flat portion ranges from −3.3 eV to −2.7 eV.

41. The light-emitting device according to claim 40, wherein a material of the flat portion comprises one or a combination of following:
ZnS;
ZnTe; or
GaP.

42. The light-emitting device according to claim 27, wherein in a same light-emitting device, a light-emitting color of the flat portion is same as a light-emitting color of the organic light-emitting layer.

43. The light-emitting device according to claim 26, wherein the first electrode layer comprises a reflecting material, and at least part of the second electrode layer is a transparent electrode.

44. A display panel, comprising the light-emitting device according to claim 26.

45. A method for manufacturing a light-emitting device, comprising:
providing a base substrate;
forming a first electrode layer on a side of the base substrate;
forming a first film layer on a side of the first electrode layer facing away from the base substrate, wherein the first film layer comprises: a middle portion, and an edge portion surrounding the middle portion; a surface of the middle portion facing away from the first electrode layer is a first distance from the base substrate, a surface of the edge portion facing away from the first electrode layer is a second distance from the base substrate, and the first distance and the second distance are different;
forming a light-emitting structure on a side of the first film layer facing away from the first electrode layer, wherein the light-emitting structure comprises an organic light-emitting layer and a flat portion, the flat portion is located in a region where a smaller one of the first distance and the second distance is located, and the flat portion matches a contact film layer in energy level, so that after being filled with the flat portion, a film thickness between a surface of the light-emitting structure facing away from the first film layer and the base substrate is consistent; and
forming a second electrode layer on a side of the light-emitting structure facing away from the first film layer.
